(19) United States
(12) Patent Application Publication
(10) Pub. No.: US 2008/0237841 A1
(43) Pub. Date: Oct. 2, 2008

(54) Microelectronic package, method of manufacturing same, and system including same

(76) Inventors: Leonel R. Arana, Phoenix, AZ (US); Vijay S. Wakharkar, Paradise Valley, AZ (US); James C. Matayabas, Chandler, AZ (US); Paul A. Koning, Chandler, AZ (US); Cynthia K. Koning, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/729,194

(22) Filed: Mar. 27, 2007

(51) Int. Cl. H01L 23/34; H01L 21/58

(52) U.S. Cl. 257/712; 438/107; 257/E21.505; 257/E23.11

(57) ABSTRACT

A microelectronic package includes a substrate (110) having a first die (120) and a second die (130) located thereon, a first thermal interface material (121) located over the first die, and a second thermal interface material (131) located over the second die. The first thermal interface material has a first set of characteristics, the second thermal interface material has a second set of characteristics, and the first set of characteristics is not identical to the second set of characteristics.

### FIELD OF THE INVENTION

The disclosed embodiments of the invention relate generally to microelectronic packages, and relate more particularly to thermal management in microelectronic packages.

### BACKGROUND OF THE INVENTION

Future generations of central processing unit (CPU) products will integrate multiple die within the CPU package in a side-by-side or other multi-chip package format to enhance performance. A cost-effective thermal solution that meets heat rejection requirements for all die is needed for such mixed-die multi-chip CPU packages, including CPU packages in which one or more of the silicon technology, die height, die size, thermal design power (TDP), or another parameter varies from one die to another.

A sophisticated and expensive thermal solution involving a backside metallization (BSM) (typically composed of layers of titanium, nickel-vanadium, and gold (Ti/NiV/Au)), an indium thermal interface material (TIM), and a copper integrated heat spreader (IHS) is currently used to reject heat from currently-manufactured multi-chip packages containing two identical CPU die. For this thermal solution to be effective, both die must have backside metallization (to enable solder to wet and adhere well), the IHS must have a patterned solder wetting pad (e.g. Ni/Au), and the die heights must be within approximately 25 micrometers of each other in order to minimize voiding and/or squeeze out. The same thermal solution may also be contemplated for a mixed-die multi-chip package, but this would require that all of the included die, even low-power die such as memory and logic die and the like, undergo BSM deposition, have approximately the same heights, and be coated with expensive indium TIM. As a reference point, indium is approximately ten times more expensive than silver. Such an approach would clearly be overly expensive and inefficient. Accordingly, there exists a need for a thermal management solution for mixed-die, multi-chip microelectronic packages that properly addresses the attendant heat rejection requirements without falling into problems of inefficiency and waste.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a microelectronic package according to an embodiment of the invention;

FIG. 2 is a flowchart illustrating a method of manufacturing a microelectronic package according to an embodiment of the invention;

FIG. 3 is a plan view showing a pre-attachment scheme for a thermal interface material according to an embodiment of the invention;

FIG. 4 is a plan view showing a pre-attachment scheme for a thermal interface material according to a different embodiment of the invention; and

FIG. 5 is a schematic view of a system including a microelectronic package according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a microelectronic package comprises a substrate having a first die and a second die located thereon, a first thermal interface material located over the first die, and a second thermal interface material located over the second die. The first thermal interface material has a first set of characteristics, the second thermal interface material has a second set of characteristics, and the first set of characteristics is not identical to the second set of characteristics. The described microelectronic package is able to be customized for the particular heat rejection requirements of two or more die within the package, even in cases where the heat rejection requirements for the die are very different from each other.

As is known in the art, semiconductor die can be attached to underlying substrates according to a variety of methods. Accordingly, where this document describes a substrate having a die “located thereon” the description encompasses all of such attachment configurations and all of the ways in which a die may be associated with a substrate, whether such configuration or association is characterized by direct physical contact between substrate and die, is characterized by solder bumps or another material lying between substrate and die, or is characterized by or includes some other feature.

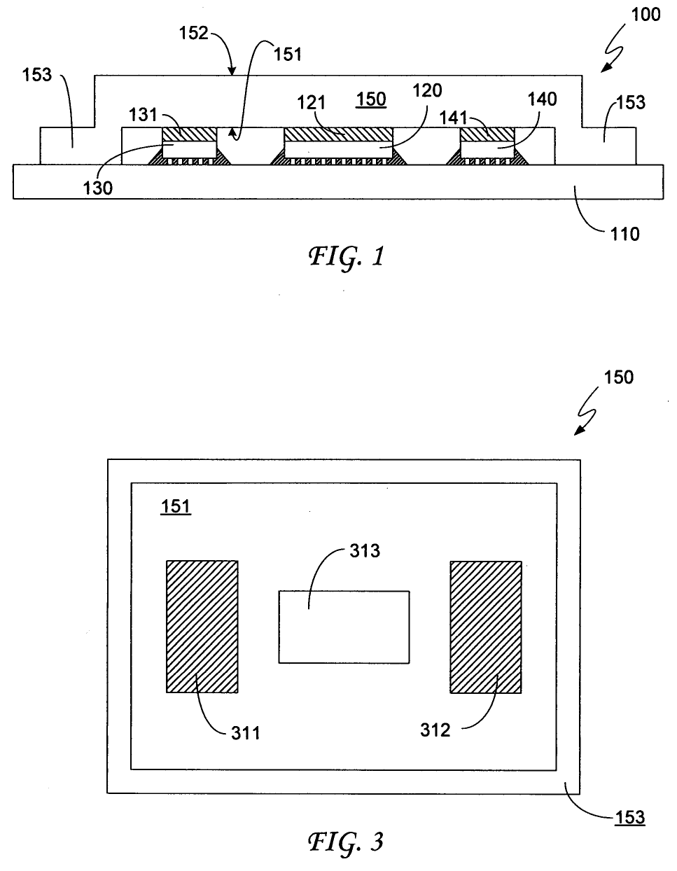

Referring now to the figures, FIG. 1 is a cross-sectional view of a microelectronic package 100 according to an embodiment of the invention. As illustrated in FIG. 1, microelectronic package 100 comprises a substrate 110 having a die 120 and a die 130 located thereon. Die 120 and die 130 may differ from each other in terms of one or more of power consumption, thermal design power, silicon technology, die height, die size, or another parameter. As an example, in some embodiments die 120 has a first height and die 130 has a second height that is different from the first height. The difference between the height of die 120 and the height of die 130 can, in certain embodiments, be greater than 25 micrometers. As a reference point, voiding or squeeze-out issues make 25 micrometers the approximate upper limit for die height difference in packages where solder thermal interface material is to be used as the thermal interface material for all dies on the package.

As another example, die 120 may be a high-power die such as a CPU die or the like and die 130 may be a relatively low-power die such as volatile or non-volatile memory, a logic die (including graphics, memory control, I/O control, or other chipset components), or the like. In other words, die 120 may have a first (higher) thermal design power and die 130 may have a second (lower) thermal design power. Microelectronic package 100 may thus be a mixed-die, multi-chip package in that at least one of the plurality of die that it contains may be different in some respect from at least another one of the plurality of die.

In the illustrated embodiment, microelectronic package 100 further comprises a die 140 on substrate 110. As an example, die 140 can be similar in one or more respects to die 120 or to die 130 or it can be completely dissimilar to die 120 and die 130. In a non-illustrated embodiment, microelectronic package 100 or a different microelectronic package can have even more than three dies, any or all of which can be similar to or dissimilar from any of the other dies in varying degrees.

A thermal interface material 121 is located over die 120 and a thermal interface material 131 is located over die 130. Similarly, a thermal interface material 141 is located over die 140. Several types of thermal interface material exist in the industry, and thermal interface materials 121, 131, and 141 may be chosen from among these various types, as further discussed below. The existing thermal interface materials fall generally into one of the following five categories: (1) thermal greases and thermal compounds; (2) elastomer pads; (3) phase change materials; (4) polymer gels; and (5) solder materials. Each of these categories will now be described in further detail.

Thermal greases and thermal compounds are low-cost materials composed of silicone oil or an alternate chemistry containing conductive fillers such as aluminum, nickel, or copper, and come in a paste format. No special die or IHS treatment is necessary with thermal greases or thermal compounds. These materials have a bulk thermal conductivity of between approximately one and five Watts per meter per degree Kelvin (W/m/K), a low interfacial resistance, poor gap filling properties (at least in part because thermal greases and compounds are generally applied in rather thin layers), and poor thermal stability.

Elastomer pads are low-cost solid or foam pre-formed elastomers containing a conductive filler or a graphite or composite sheet. Many types are highly compliant and thus deform easily in order to accommodate varying gap heights. No special die or IHS treatment is necessary. Elastomer pads have a bulk thermal conductivity of between approximately one and ten W/m/K, a moderate to high interfacial resistance, excellent gap filling properties (as mentioned), and excellent thermal stability.

Phase change materials are low-cost materials that undergo a transition from solid to liquid phase when heat is applied to them. They are solids at room temperatures and paste-like liquids at die operating temperatures, but may also be dispensed as a pre-formed material. Phase change materials do not require any special die or IHS treatment. They have a bulk thermal conductivity of between approximately one and five W/m/K, a low interfacial resistance, moderate gap filling properties, and moderate thermal stability.

Polymer gels are moderately expensive crosslinkable polymers (such as silicone or the like) filled with a metal (such as aluminum or silver) or with a ceramic (such as aluminum oxide or zinc oxide). They are generally dispensed as a paste and cured in situ (within the package). Polymer gels do not require any special die or IHS treatment. They have a bulk thermal conductivity of between approximately 1 and 5 W/m/K, a low interfacial resistance, moderate gap filling properties, and excellent thermal stability.

Solder materials are metals or alloys having a low melting point. Some solder materials, such as indium, are very expensive; others are relatively inexpensive but have disadvantages in practice relative to indium, notably higher yield strength and/or higher melting points, resulting in higher stresses in the package. Solder is generally placed on the die as a preform or paste (solder balls with flux/vehicle) and is reflowed to create a connection between the die and the IHS. Solder materials require special die and IHS treatment in that they require BSM on the die and a wetting pad on the IHS. Solder has a bulk thermal conductivity as high as approximately 80 W/m/K (in the case of indium solder), a low interfacial resistance, and moderate gap filling properties, and can have excellent thermal stability (as dictated by the melting temperature of the solder).

As suggested by the foregoing paragraphs, each one of the various types of thermal interface materials has its own set of characteristics. Some of the characteristics within each material's set of characteristics, (bulk thermal conductivity, interfacial resistance, cost, thermal stability, etc.) have been explicitly mentioned above. It may be seen that a thermal interface material's set of characteristics make that particular material better suited for use with certain kinds of dies and in certain situations and environments and less well suited for certain other kinds of dies and in certain other situations and environments. Microelectronic package 100, as well as other microelectronic packages according to embodiments of the invention, pair particular types of thermal interface materials with particular types of dies in order to create an ideal or appropriate match between the two.

Referring still to microelectronic package 100, thermal interface material 121 has a first set of characteristics, thermal interface material 131 has a second set of characteristics, and the first set of characteristics is not identical to the second set of characteristics. In one embodiment, thermal interface material 121 is one of the five types of thermal interface materials mentioned above (thermal grease/thermal compound; elastomer pad; phase change material; polymer gel; and solder material) and thermal interface material 131 is a different one of those five types of thermal interface material. In a different embodiment, thermal interface material 121 and thermal interface material 131 are both of the same type yet have sets of characteristics that differ from each other in some respects, such as when thermal interface material 121 is, for example, an indium solder and thermal interface material 131 is, for example, a different kind of solder—perhaps one that is less expensive than indium solder or is cheaper to apply but that has a bulk thermal conductivity that is not quite as high.

In an embodiment such as that introduced above (in which die 120 has a first thermal design power and die 130 has a second thermal design power that is lower than the first thermal design power), a solder material—such as indium solder—may be used for thermal interface material 121 because solder's excellent bulk thermal conductivity enables it to very effectively conduct away from die 120 the relatively large amounts of heat generated by die 120. Meanwhile, an elastomer pad or a phase change material may be used for thermal interface material 131 because both elastomer pads and phase change materials are significantly less expensive than solder and, although both are less effective than solder for heat removal purposes, die 130 would not (in the embodiment under discussion) generate enough heat for that lesser heat-removal effectiveness to be problematic. By judiciously matching a thermal interface material type to the die with which it is associated, as in the embodiment just described, a cost-effective heat removal solution for a mixed-die, multi-chip microelectronic package may be achieved.

It is very common for at least one of the dies in a microelectronic package to be a high-power die, and therefore it is quite typical for one of the package's thermal interface materials—the material associated with the high-power die—to be a solder material. A second thermal interface material—one that is intended for use with a lower-power die in the same microelectronic package as the high-power die—should, in order to integrate effectively with the solder thermal interface material: (1) preferably be in a preform format so as to represent minimal process impact (i.e., so as to not require an additional dispense station); (2) survive the reflow profile for solder thermal interface material (e.g., a peak temperature of approximately 175° Celsius for indium reflow) without degrading or substantially outgassing; (3) not negatively affect the solder material or its processing, and should not be affected by the solder or by the flux used to activate it; (4) work with low clamping pressure so as not to affect the quality of the solder; and (5) exhibit little or no bleed-out, voiding, or pump-out (sometimes referred to as squeeze-out) so as to not substantially degrade in performance over time.

Thermal greases and compounds suffer from pump-out and thus may not have the required thermal stability. They would also require a separate dispense station because they are not available in a pre-form format. Polymer gels would likely offer the necessary thermal stability but, like thermal greases and compounds, would require a separate dispense station. In addition, out-gassing from the polymer gel may adversely affect the solderability of the solder, while certain solder flux components may poison the polymer gel catalyst.

In contrast to polymer gels and thermal greases and compounds, phase change materials and elastomer pads are available as preforms (and thus may be placed on the die using the same tool that places the solder preform), are much less likely to negatively interact with the solder materials and process (because they do not require in situ curing), and offer more than adequate thermal resistance and bleed/pump performance. Phase change materials and elastomer pads are thus very well suited to act as a thermal interface material for one or more of the die in a microelectronic package according to an embodiment of the invention.

In the embodiment illustrated in FIG. 1, microelectronic package 100 further comprises an integrated heat spreader 150 over dies 120, 130, and 140. In one embodiment, integrated heat spreader 150 is attached to die 120 by thermal interface material 121 and attached to die 130 by thermal interface material 131. Integrated heat spreader 150 comprises a surface 151, a surface 152 opposite surface 151, and a lip 153 that sits on substrate 110. As known in the art, a heat spreader can be made of a thermally conductive material and can assist in the transfer of heat away from a heat source such as a semiconductor die.

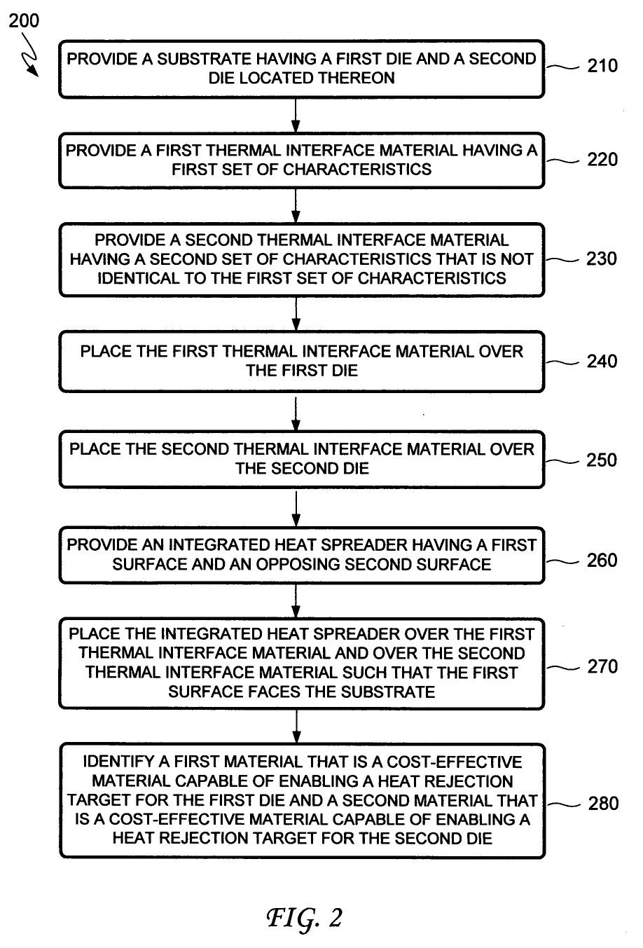

FIG. 2 is a flowchart illustrating a method 200 of manufacturing a microelectronic package according to an embodiment of the invention. A step 210 of method 200 is to provide a substrate having a first die and a second die located thereon. As an example, the substrate, the first die, and the second die can be similar to, respectively, substrate 110, die 120, and die 130, all of which are shown in FIG. 1.

A step 220 of method 200 is to provide a first thermal interface material having a first set of characteristics. As an example, the first thermal interface material can be similar to can be similar to 121, shown in FIG. 1.

A step 230 of method 200 is to provide a second thermal interface material having a second set of characteristics that is not identical to the first set of characteristics. As an example, the second thermal interface material can be similar to thermal interface material 131, shown in FIG. 1.

A step 240 of method 200 is to place the first thermal interface material over the first die. In one embodiment, step 240 comprises placing the first thermal interface material onto the first die. As an example, placing the first thermal interface material onto the first die can be done using a dispensing operation (in which thermal interface material in paste or other malleable form is dispensed onto the die using a dispensing station or other dispensing tool), a pick and place operation (in which thermal interface material in a pre-form format is picked up from a tray or the like and placed on the die by a robot arm or other placement mechanism), a pre-attach operation (in which thermal interface material is placed on a component of the microelectronic package other than the die so as to be on or over the die following package assembly), or the like. As suggested above by the references to paste and pre-form formats, not all types of thermal interface material are compatible with one or more of the three placement methods described in this paragraph. In fact, a particular thermal interface material's compatibility with a certain placement method may represent a significant advantage for that thermal interface material over another thermal interface material that is not so compatible.

A step 250 of method 200 is to place the second thermal interface material over the second die. In one embodiment, step 250 comprises placing the second thermal interface material onto the second die. As an example, placing the second thermal interface material onto the second die can be done using a dispensing operation, a pick and place operation, a pre-attach operation, or the like. Each of these operations was discussed in additional detail above.

A step 260 of method 200 is to provide an integrated heat spreader having a first surface and an opposing second surface. As an example, the integrated heat spreader, the first surface, and the second surface can be similar to, respectively, integrated heat spreader 150, surface 151, and surface 152, all of which are shown in FIG. 1.

A step 270 of method 200 is to place the integrated heat spreader over the first thermal interface material and over the second thermal interface material such that the first surface faces the substrate. In certain embodiments where the microelectronic package includes an intergrated heat spreader, placing one or more of the thermal interface materials on or over its associated die can comprise pre-attaching the thermal interface material to a portion of the intergrated heat spreader prior to the integration of the integrated heat spreader into the microelectronic package. As an example, step 240, step 250, or both can comprise placing the corresponding thermal interface material onto the first surface of the integrated heat spreader.

The concept of pre-attaching a thermal interface material to the first surface of the thermal interface material will now be discussed in greater detail using an example in which it is the second thermal interface material being thus pre-attached so as to eventually be located over the second die. This discussion will from time to time make reference to a surface area of the second die. It should be understood that the following discussion may also apply in situations involving thermal interface materials other than the second thermal interface material, and dies other than the second die.

In one embodiment of the example under discussion, placing the second thermal interface material (step 250) comprises placing the second thermal interface material on the integrated heat spreader, and doing so only in an area having a size that is approximately equal to the surface area of the second die. The area in which the second thermal interface material is placed is chosen such that it will be located on or over the second die after the integrated heat spreader is positioned over the substrate during assembly of the microelectronic package. An example of this embodiment is illustrated in FIG. 3.

FIG. 3 depicts integrated heat spreader 150 such that surface 151 is visible. Integrated heat spreader 150 as it is illustrated in FIG. 3 is prepared for use with a substrate such as substrate 110 that is illustrated in FIG. 1 and described above, namely, a substrate that has a high-power die located between dies of relatively lower power. As shown, a thermal interface material 311 and a thermal interface material 312 are placed on surface 151 of integrated heat spreader 150 so as to eventually be respectively located over dies 130 and 140 (see FIG. 1). As an example, and for reasons discussed above, among other possible reasons, thermal interface material 311 and/or thermal interface material 312 can be one of a pre-applied elastomer and a phase change material. As is also shown in FIG. 3, integrated heat spreader 150 further comprises a solder wetting pad 313 positioned so as to be eventually located over high-power die 120 (see FIG. 1).

In a different embodiment of the example under discussion, placing the second thermal interface material (step 250) comprises placing the second thermal interface material on the integrated heat spreader in an area having a size that is greater than the surface area of the second die. In a particular manifestation of this embodiment, the thermal interface material is placed so as to cover all or substantially all of the first surface of the integrated heat spreader. This embodiment, which is illustrated in FIG. 4, eliminates the need to identify a particular portion of the integrated heat spreader that will be located over the second die after the integrated heat spreader is attached and the microelectronic package assembled. Instead, as indicated, the thermal interface material is simply placed everywhere on the first surface of the integrated heat spreader, or at least over an area of that surface that is large enough to include all or substantially all locations that could possibly end up being over the second die following package assembly and attachment of the integrated heat spreader.

Like FIG. 3, FIG. 4 depicts integrated heat spreader 150 such that surface 151 is visible and depicts an embodiment of integrated heat spreader 150 that is prepared for use with a substrate such as substrate 110 that is illustrated in FIG. 1 and described above, namely, a substrate that has a high-power die located between dies of relatively lower power. As shown, a thermal interface material 411 is placed on surface 151 of integrated heat spreader 150 so as to cover all or substantially all of surface 151. As mentioned above, placing thermal interface material 411 in this fashion eliminates any need to identify a particular portion of the integrated heat spreader that will be located over a particular die after the integrated heat spreader is attached and the microelectronic package assembled. Instead, because the thermal interface material is simply placed everywhere or almost everywhere on surface 151, the thermal interface material will very likely be located over the appropriate die regardless of the eventual placement of that die on substrate 110.

As an example, and for reasons discussed above, among other possible reasons, thermal interface material 411 can be one of a pre-applied elastomer and a phase change material. As is also shown in FIG. 4, integrated heat spreader 150 further comprises a solder wetting pad 413 positioned so as to be eventually located over high-power die 120 (see FIG. 1). It should be understood that the thermal interface material pre-placement techniques discussed here may also apply to substrates having a different number and/or physical layout of dies.

A step 280 of method 200 is to identify a first material that is a cost-effective material capable of enabling a heat rejection target for the first die and a second material that is a cost-effective material capable of enabling a heat rejection target for the second die. As an example, the first material and the second material can each be one or another of the five types of thermal interface material described above. Steps 220 and 230 can then comprise, respectively, providing the first material and providing the second material. (It should be understood that although this step 280 is introduced after the introduction of steps 220 and 230 in this method 200, step 280 may be performed before the performance of steps 220 and 230.)

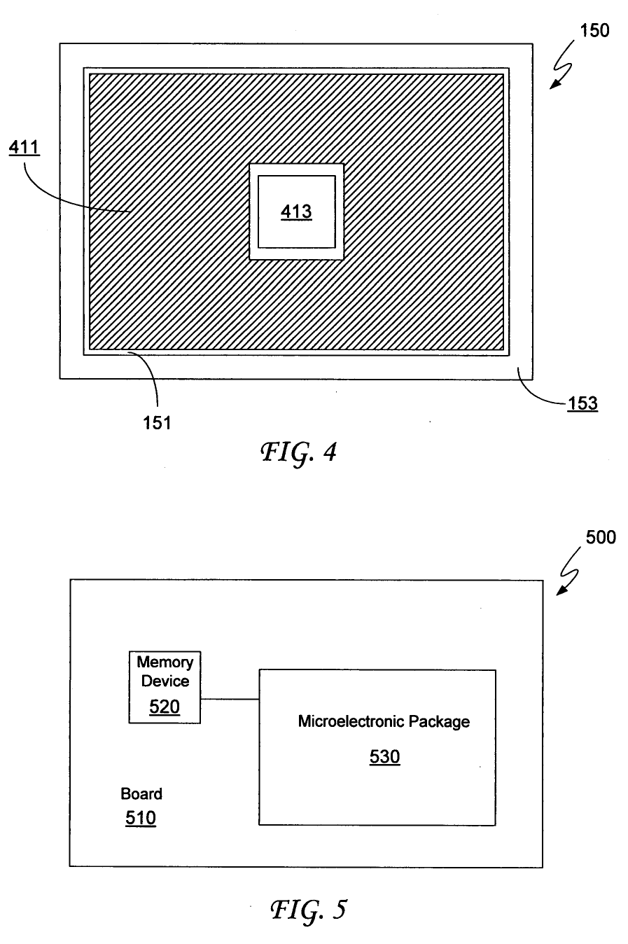

FIG. 5 is a schematic view of a system 500 including a microelectronic package according to an embodiment of the invention. As illustrated in FIG. 5, system 500 comprises a board 510, a memory device 520 disposed on board 510, and a microelectronic package 530 disposed on board 510 and coupled to memory device 520. Although they are not explicitly illustrated in FIG. 5, microelectronic package 530 comprises a substrate having a first die and a second die located thereon, a first thermal interface material located over the first die, and a second thermal interface material located over the second die, wherein the first thermal interface material has a first set of characteristics, the second thermal interface material has a second set of characteristics, and the first set of characteristics is not identical to the second set of characteristics. In one embodiment, microelectronic package 530 further comprises an integrated heat spreader over the first die and the second die. As an example, microelectronic package 530 and its components can be similar to microelectronic package 100, first shown in FIG. 1, and its corresponding components.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic package and the related methods and systems discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A microelectronic package comprising:
a substrate having a first die and a second die located thereon;
a first thermal interface material located over the first die; and
a second thermal interface material located over the second die,
wherein:
the first thermal interface material has a first set of characteristics, the second thermal interface material has a second set of characteristics, and the first set of characteristics is not identical to the second set of characteristics.

2. The microelectronic package of claim 1 wherein:
the first thermal interface material is one of a thermal grease, an elastomer pad, a phase change material, a polymer gel, and a solder material and the second thermal interface material is a different one of the thermal grease, the elastomer pad, the phase change material, the polymer gel, and the solder material.

3. The microelectronic package of claim 2 wherein:
the first thermal interface material is the solder material and the second thermal interface material is one of the elastomer pad and the phase change material.

4. The microelectronic package of claim 1 further comprising:
an integrated heat spreader over the first die and the second die.

5. The microelectronic package of claim 4 wherein:
the integrated heat spreader is attached to the first die by the first thermal interface material and attached to the second die by the second thermal interface material.

6. The microelectronic package of claim 1 wherein:
the first die has a first thermal design power and the second die has a second thermal design power that is different from the first thermal design power.

7. The microelectronic package of claim 6 wherein:
the first die has a first height and the second die has a second height that is different from the first height.

8. A method of manufacturing a microelectronic package, the method comprising:
providing a substrate having a first die and a second die located thereon;
providing a first thermal interface material having a first set of characteristics;
providing a second thermal interface material having a second set of characteristics that is not identical to the first set of characteristics;
placing the first thermal interface material over the first die; and
placing the second thermal interface material over the second die.

9. The method of claim 8 further comprising:
providing an integrated heat spreader having a first surface and an opposing second surface; and
placing the integrated heat spreader over the first thermal interface material and over the second thermal interface material such that the first surface faces the substrate.

10. The method of claim 9 wherein:
placing the first thermal interface material comprises placing the first thermal interface material onto the first die; and
placing the second thermal interface material comprises placing the second thermal interface material onto the first surface of the integrated heat spreader.

11. The method of claim 10 wherein:
the second die has a surface area; and
placing the second thermal interface material comprises placing the second thermal interface material only in an area having a size that is approximately equal to the surface area.

12. The method of claim 10 wherein:
the second die has a surface area; and
placing the second thermal interface material comprises placing the second thermal interface material in an area having a size that is greater than the surface area.

13. The method of claim 8 wherein:
placing the first thermal interface material comprises placing the first thermal interface material onto the first die; and
placing the second thermal interface material comprises placing the second thermal interface material onto the second die.

14. The method of claim 13 wherein:
placing the first thermal interface material comprises one of dispensing the first thermal interface material onto the first die and placing the first thermal interface material onto the first die using a pick and place operation; and
placing the second thermal interface material comprises one of dispensing the second thermal interface material onto the second die and placing the second thermal interface material onto the second die using a pick and place operation.

15. The method of claim 8 further comprising:
identifying a first material that is a cost-effective material capable of enabling a heat rejection target for the first die; and
identifying a second material that is a cost-effective material capable of enabling a heat rejection target for the second die,
wherein:
providing the first thermal interface material comprises providing the first material; and
providing the second thermal interface material comprises providing the second material.

16. A system comprising:
a board;
a memory device disposed on the board; and
a microelectronic package disposed on the board and coupled to the memory device,
wherein:
the microelectronic package comprises:
a substrate having a first die and a second die located thereon;
a first thermal interface material located over the first die; and
a second thermal interface material located over the second die; and
the first thermal interface material has a first set of characteristics, the second thermal interface material has a second set of characteristics, and the first set of characteristics is not identical to the second set of characteristics.

17. The system of claim 16 further comprising:
an integrated heat spreader over the first die and the second die.

18. The system of claim 17 wherein:
the first thermal interface material is one of a thermal grease, an elastomer pad, a phase change material, a polymer gel, and a solder material and the second thermal interface material is a different one of the thermal grease, the elastomer pad, the phase change material, the polymer gel, and the solder material.

19. The system of claim 18 wherein:
the integrated heat spreader is attached to the first die by the first thermal interface material and attached to the second die by the second thermal interface material.

20. The system of claim 19 wherein:
the first die has a first thermal design power and the second die has a second thermal design power that is different from the first thermal design power; and
the first die has a first height and the second die has a second height that is different from the first height.
